(19) United States
(12) Patent Application Publication
(10) Pub. No.: US 2025/0374597 A1
(43) Pub. Date: Dec. 4, 2025

(54) DISPLAY PANEL AND DISPLAY DEVICE

(71) Applicant: Guangzhou China Star Optoelectronics Semiconductor Display Technology Co., LTd., Guangzhou, Guangdong (CN)

(72) Inventors: Qiang WANG, Guangzhou, Guangdong (CN); Lanlan LI, Guangzhou, Guangdong (CN)

(73) Assignee: Guangzhou China Star Optoelectronics Semiconductor Display Technology Co., LTd., Guangzhou, Guangdong (CN)

(21) Appl. No.: 18/870,663

(22) PCT Filed: Oct. 31, 2023
(86) PCT No.: PCT/CN2023/128151

§ 371 Date: Nov. 30, 2024

(30) Foreign Application Priority Data
Mar. 28, 2023 (CN) 202310318925.X

(51) Int. Cl. H10D 30/67; H10D 30/01; H10D 86/60

(52) U.S. Cl. CPC H10D 30/6704; H10D 30/6732; H10D 30/6755; H10D 86/60; H10D 30/0316

(57) ABSTRACT

Disclosed are a display panel and a display device including a thin film transistor that is disposed on a substrate and includes an active portion. The display panel further includes a first insulating layer disposed on a side of the active portion away from the substrate, and a protective portion disposed on a side of the first insulating layer away from the substrate. An orthographic projection of the protective portion on the substrate at least partially covers an orthographic projection of the active portion on the substrate. The protective portion includes a hydrogen blocking portion and a hydrogen trapping portion stacked in a direction perpendicular to the substrate.

### TECHNICAL FIELD

The present disclosure relates to the field of display technologies, and more particularly, to a display panel and a display device.

### BACKGROUND

Thin film transistors (TFTs) of display panels include active layers that generally are made of a silicon-based material, such as an amorphous silicon (a—Si) material, which is high in stability and excellent in processability.

At present, with the development of display technology, metal oxide semiconductor materials (e.g., indium gallium zinc oxide (IGZO)) are used to prepare the active layers of the thin-film transistors, and have gradually attracted people's attention. The metal oxide thin film transistor has a higher mobility than the amorphous silicon thin film transistor, but has a poor stability. In the manufacturing process of the display panel, hydrogen atoms may be introduced, so that a channel region of an active layer is eroded when the hydrogen atoms are diffused to the active layer, causing a threshold voltage of the thin film transistor to drift, affecting the operation stability of the thin film transistor, and even resulting in poor display.

### SUMMARY

The present disclosure provides a display panel and a display device, which can solve the problem of poor display caused by erosion of an active portion of the display panel by hydrogen atoms.

To solve the above problem, according to a first aspect, the present disclosure provides a display panel including:
a substrate; and
a thin film transistor disposed on the substrate and including an active portion.

The display panel further includes a first insulating layer disposed on a side of the active portion away from the substrate, and a protective portion disposed on a side of the first insulating layer away from the substrate. An orthographic projection of the protective portion on the substrate at least partially covers an orthographic projection of the active portion on the substrate, and the protective portion includes a hydrogen blocking portion and a hydrogen trapping portion stacked in a direction perpendicular to the substrate.

According to a second aspect, the present disclosure provides a display device including a display panel, the display panel including:
a substrate; and
a thin film transistor disposed on the substrate and including an active portion.

The display panel further includes a first insulating layer disposed on a side of the active portion away from the substrate, and a protective portion disposed on a side of the first insulating layer away from the substrate. An orthographic projection of the protective portion on the substrate at least partially covers an orthographic projection of the active portion on the substrate, and the protective portion includes a hydrogen blocking portion and a hydrogen trapping portion stacked in a direction perpendicular to the substrate.

### BRIEF DESCRIPTION OF THE DRAWINGS

FIG. 1 is a schematic sectional view of a first display panel according to some embodiments of the present disclosure.

FIG. 2 is a schematic sectional view of a second display panel according to some embodiments of the present disclosure.

FIG. 3 is a schematic sectional view of a third display panel according to some embodiments of the present disclosure.

FIGS. 4a-4g are a schematic flowchart of a method for preparing a display panel according to some embodiments of the present disclosure.

### DETAILED DESCRIPTION OF EMBODIMENTS

In the following, the technical solutions in the embodiments of the present disclosure will be clearly and fully described in connection with the accompanying drawings in the embodiments of the present disclosure. It will be apparent that the described embodiments are merely a part of the embodiments of the present disclosure, rather than all the embodiments. Based on the embodiments in the present disclosure, all other embodiments obtained by a person skilled in the art without involving any inventive effort fall within the scope of the present disclosure.

In the description of the present disclosure, it is to be understood that terms indicating the azimuth or positional relationship, such as “center”, “longitudinal”, “transverse”, “length”, “width”, “thickness”, “up”, “down”, “front”, “back”, “left”, “right”, “vertical”, “horizontal”, “top”, “bottom”, “inside”, and “outside”, are based on the azimuth or positional relationship shown in the drawings. These terms are used merely for purposes of describing the present disclosure and simplifying the description, rather than indicating or implying that the indicated device or element must have a particular azimuth, or be constructed and operated in a particular azimuth, and therefore the terms are not to be construed as limiting the present disclosure. Furthermore, terms “first” and “second” are used for descriptive purposes only and are not to be construed as indicating or implying relative importance or implying the number of indicated technical features. Accordingly, the features defined by the “first” and the “second” may include, expressly or implicitly, one or more of said features. In the description of the present disclosure, “plurality” means two or more, unless expressly and specifically defined otherwise.

In the present disclosure, the term “exemplary” is used to mean “serving as an example, illustration, or explanation”. Any embodiment described herein as “exemplary” is not necessarily to be construed as preferred or advantageous over other embodiments. To enable any person skilled in the art to make and use the present disclosure, the following description is given. In the following description, details are set forth for purposes of explanation. It is to be understood by those of ordinary skill in the art that the present disclosure may be practiced without these specific details. In other examples, well-known structures and procedures will not be set forth in detail so as not to obscure the description of the present disclosure with unnecessary detail. Thus, the present disclosure is not intended to be limited to the embodiments shown, but is to be accorded the widest scope consistent with the principles and features disclosed herein.

Embodiments of the present disclosure provide a display panel, which is described in detail below with reference to the accompanying drawings.

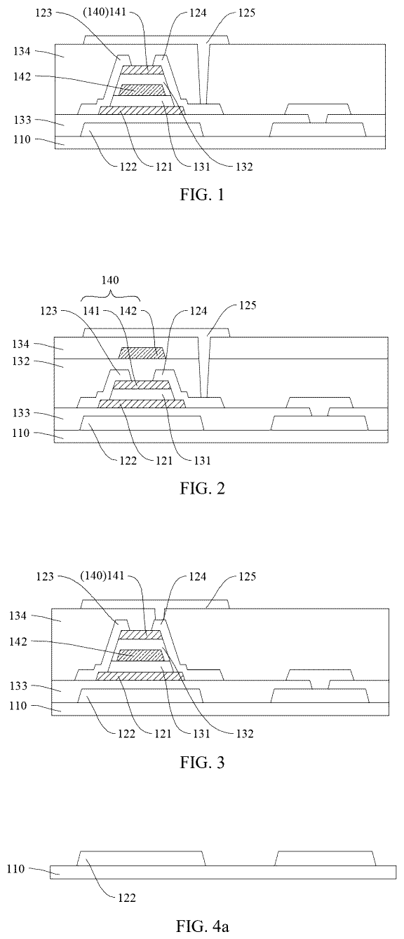

Referring to FIG. 1, the display panel includes a substrate 110 and a plurality of thin film transistors (one of which is illustratively shown) disposed on the substrate 110. Each thin film transistor includes a gate 122, an active portion 121 disposed corresponding to and insulated from the gate 122, and a source 123 and a drain 124 respectively overlapped with the active portion 121.

The display panel further includes a first insulating layer 131 disposed on a side of the active portion 121 away from the substrate 110, and a protective portion 140 disposed on a side of the first insulating layer 131 away from the substrate 110. An orthographic projection of the protective portion 140 on the substrate 110 at least partially overlaps an orthographic projection of the active portion 121 on the substrate 110. The protective portion 140 includes a hydrogen blocking portion 142 and a hydrogen trapping portion 141 that are stacked in a direction perpendicular to the substrate 110. The hydrogen trapping portion 141 is disposed on a side of the hydrogen blocking portion 142 adjacent to the active portion 121, as shown in FIG. 2. Alternatively, the hydrogen trapping portion 141 is disposed on a side of the hydrogen blocking portion 142 away from the active portion 121, as shown in FIG. 1.

According to the display panel described in the embodiments of the present disclosure, the hydrogen blocking portion 142 and the hydrogen trapping portion 141 that are insulated from the active portion 121 are provided on a side of the active portion 121 away from the substrate. The hydrogen blocking portion 142, which can be interpreted as a barrier structure for blocking diffusion of hydrogen atoms, are be disposed on the side of the active portion 121 away from the substrate 110, so that a path through which hydrogen atoms diffuse are effectively cut off from the side of the hydrogen blocking portion 142 away from the active portion 121 toward the active portion 121, thereby greatly reducing the number of hydrogen atoms diffused into the active portion 121 during preparation and use of the display panel. Furthermore, the hydrogen trapping portion 141, which can be interpreted as a structure for trapping free hydrogen atoms in the display panel, is disposed on the side of the hydrogen blocking portion 142 adjacent to or away from the active portion 121, so that hydrogen atoms diffused into the active portion 121 can be effectively absorbed, reducing the number of hydrogen atoms diffused into the active portion 121.

In view of the above, the hydrogen trapping portion 141 and the hydrogen blocking portion 142 in the protection portion 140 cooperate to reduce the number of hydrogen atoms diffused into the active section 121 during the preparation and use of the display panel, thereby avoiding the problem of drift in the performance of the thin film transistor caused by excessive hydrogen atoms in the active portion 121, thereby improving the display yield and reliability of the display panel.

In some embodiments, a material of the hydrogen trapping portion 141 may be any material having a good hydrogen trapping effect. For the sake of the production cost of the display panel, a metal oxide semiconductor material conventionally used in the display panel may be selected to prepare the hydrogen trapping portion 141. For example, a material of the hydrogen blocking portion 142 is selected from indium gallium zinc oxide, indium tin zinc oxide, indium zinc oxide, or lanthanide rare earth-doped indium zinc oxide.

In some embodiments, a material of the hydrogen blocking portion 142 may be selected from any material having a good hydrogen blocking effect. For the sake of production cost of the display panel, a metal material conventionally used in a display panel may be selected to prepare the hydrogen blocking portion 142. For example, the material of the hydrogen blocking portion 142 is selected from copper, aluminum, titanium, molybdenum, or niobium.

In some embodiments, the thin film transistor is of a top-gate structure or a bottom-gate structure according to a specific process requirement. Referring to FIG. 1, when the thin film transistor is a bottom-gate structure, the gate 122 is disposed on a side of the active portion 121 adjacent to the substrate 110. A third insulating layer 133 is provided between the gate 122 and the active portion 121. The source 123 and the drain 124 are provided at intervals and overlapped with opposite ends of the active portion 121. In this structure, no metal thin film structure is disposed on the side of the active portion 121 away from the substrate 110, so that the active portion 121 of the thin film transistor is more vulnerable to attack of hydrogen atoms than the thin film transistor having the top-gate structure. Therefore, when the thin film transistor has the bottom-gate structure, the use of the hydrogen trapping portion 141 and the hydrogen blocking portion 142 on the side of the active portion 121 away from the substrate 110 can avoid the occurrence of diffusion of excessive hydrogen atoms to the active portion 121.

In some embodiments, referring to FIG. 1, the source 123 and the drain 124 are at least partially disposed on the side of the active portion 121 away from the substrate 110, and are made of a metal, so that the source 123 and the drain 124 can also have the effect of blocking the diffusion of hydrogen atoms to the active portion 121. Accordingly, in the direction perpendicular to the substrate 110, the source 123, the hydrogen blocking portion 142, and the drain 124 are provided so as to continuously and completely cover the active portion 121. That is, orthographic projections of the source 123, the drain 124, and the hydrogen blocking portion 142 on the substrate 110 overlap the orthographic projection of the active portion 121 on the substrate 110. As such, the combination of the source 123, the drain 124, and the hydrogen blocking portion 142 can be regarded as a hydrogen atom blocking barrier that completely cover the active portion 121, enhancing the effect of blocking the diffusion of hydrogen atoms to the active portion 121.

In some embodiments, referring to FIG. 1, the display panel further includes a first gate wiring and a second gate wiring. The first gate wiring is electrically connected to the gate 122 and configured to send a first gate voltage signal to the gate 122, and the second gate wiring is electrically connected to the hydrogen blocking portion 142 and configured to send a second gate voltage signal to the hydrogen blocking portion 142.

According to the display panel described in the embodiments of the present disclosure, when the hydrogen blocking portion 142 is made of a metal and disposed on the side of the active portion 121 away from the substrate 110, the hydrogen blocking portion 142 can also be used as another gate of the active portion 121. That is, the gate 122 is regarded as a first gate, and the hydrogen blocking portion 142 is regarded as a second gate of the active portion 121 used in conjunction with the gate 122. When the thin film transistor is operated, the gate 122 and the hydrogen blocking portion 142 together apply a voltage signal to the active portion 121, thereby enhancing the control to the active portion 121 and improving the stability of the thin film transistor, as compared to only by the gate 122 applying a voltage signal to the active portion 121.

It is noted that the first gate wiring and the second gate wiring are not specifically shown in the figures. The first gate wiring is disposed at the same layer as the gate 122 and of the same material. The second gate wiring is disposed at the same layer as the hydrogen blocking portion 142 and of the same material.

In some embodiments, on the basis of the above-described dual-gate structure, when the hydrogen trapping portion 141 is made of a metal oxide semiconductor material and is provided corresponding to the hydrogen blocking portion 142, the hydrogen trapping portion 141 is also used as the second active portion to further optimize the performance of the thin film transistor. Specifically, referring to FIG. 1, a second insulating layer 132 is further disposed between the hydrogen trapping portion 141 and the hydrogen blocking portion 142, and the source 123 and the drain 124 are respectively overlapped with opposite ends of the hydrogen trapping portion 141. Thus, in the thin film transistor of the display panel, the active portion 121 and the hydrogen trapping portion 141 are respectively overlapped with the source 123 and the drain 124 to form a dual-channel structure, so that the electron mobility of the thin film transistor can be significantly improved without increasing the area occupied by the thin film transistor.

In some embodiments, referring to FIG. 2, the hydrogen trapping portion 141 is disposed on a side of the hydrogen blocking portion 142 close to the active portion 121, and the first insulating layer 131 and the hydrogen trapping portion 141 are disposed on the active portion 121 in sequence. The first insulating layer 131 partially covers the active portion 121 so that a first end and a second end opposite to the first end of the active portion 121 are exposed. The source 123 extends from a first end of the active portion 121 along a side wall of the first insulating layer 131 to a first end of the hydrogen trapping portion 141, the drain 124 extends from a second end of the active portion 121 along another side wall of the first insulating layer 131 to a second end of the hydrogen trapping portion 141, the second insulating layer 132 covers the hydrogen trapping portion 141, the source 123, and the drain 124, and the hydrogen blocking portion 142 is disposed on the second insulating layer 132.

According to the display panel in the embodiments of the present disclosure, the gate 122 applies the first gate voltage signal to the active portion 121, and the hydrogen blocking portion 142 applies the second gate voltage signal to the hydrogen trapping portion 141. Since the hydrogen blocking portion 142 is disposed on a side of the hydrogen trapping portion 141 and the active portion 121 away from the substrate 110, the hydrogen blocking portion 142 can function to prevent hydrogen ions from diffusing into the hydrogen trapping portion 141 and the active portion 121.

In some embodiments, referring to FIG. 1, the hydrogen trapping portion 141 is disposed on the side of the hydrogen blocking portion 142 away from the active portion 121, and the first insulating layer 131, the hydrogen blocking portion 142, the second insulating layer 132, and the hydrogen trapping portion 141 are disposed on the active portion 121 in sequence. The first insulating layer 131 partially covers the active portion 121 so that the first end and the second end opposite to the first end of the active portion 121 are exposed. The hydrogen blocking portion 142 partially covers the first insulating layer 131, the second insulating layer 132 is disposed on the hydrogen blocking portion 142 and the first insulating layer 131 and covers sidewalls of the hydrogen blocking portion 142, the hydrogen trapping portion 141 is disposed on the second insulating layer 132, the source 123 extends from the first end of the active portion 121 along sidewalls of the first insulating layer 131 and the second insulating layer 132 to the first end of the hydrogen trapping portion 141, and the drain 124 extends from the second end of the active portion 121 along another sidewalls of the first insulating layer 131 and the second insulating layer 132 to the second end of the hydrogen trapping portion 141.

According to the display panel in the embodiments of the present disclosure, the gate 122 applies the first gate voltage signal to the active portion 121, and the hydrogen blocking portion 142 applies the second gate voltage signal to the hydrogen trapping portion 141 and the active portion 121. Since the hydrogen blocking portion 142 exists between the active portion 121 and the hydrogen trapping portion 141, it is possible to effectively prevent interaction between the active portion 121 and the hydrogen trapping portion 141 due to the close distance.

In some embodiments, the material of the active portion 121 is the same as the material of the hydrogen trapping portion 141. Illustratively, both the material of the active portion 121 and the material of the hydrogen trapping portion 141 are metal oxide semiconductor materials. Specifically, both the material of the active portion 121 and the material of the hydrogen trapping portion 141 are indium gallium zinc oxide.

In some embodiments, the material of the active portion 121 is different from the material of the hydrogen trapping portion 141. Illustratively, the material of the hydrogen trapping portion 141 is a metal oxide semiconductor material, the material of the active portion 121 is a silicon-based semiconductor material. Specifically, the material of the active portion 121 is low-temperature polysilicon, and the material of the hydrogen trapping portion 141 is indium gallium zinc oxide.

In some embodiments, the display panel further includes a fourth insulating layer 134 and an electrode portion 125.

Referring to FIG. 1, the fourth insulating layer 134 is disposed on the third insulating layer 133, the source 123, the drain 124, and the hydrogen trapping portion 141. The electrode portion 125 is connected to the drain 124 through a via hole in the fourth insulating layer 134.

Referring to FIG. 2, the fourth insulating layer 134 is disposed on the second insulating layer 132 and the hydrogen blocking portion 142, and the electrode portion 125 is connected to the drain 124 through via holes in the fourth insulating layer 134 and the second insulating layer 132.

In some embodiments, the display panel is a liquid crystal display panel and the electrode portion 125 is a pixel electrode.

In some embodiments, the display panel is an organic light emitting display panel, and the electrode portion 125 serves as an anode of the organic light emitting device.

In some embodiments, referring to FIG. 3, on the basis of the display panel shown in FIG. 1, the connection position of the electrode portion 125 and the drain 124 is adjusted. For example, a via hole for connecting the electrode portion 125 and the drain 124 is provided in a portion corresponding to a connection between the drain 124 and the hydrogen trapping portion 141, thereby greatly reducing the depth of the via hole, and reducing the risk that the electrode portion 125 is broken at the via hole.

It is to be noted that the above embodiments merely describe the above structures of the display panel, and it is to be understood that in addition to the above-described structures, any other structures may be included in the display panel according to the embodiments of the present disclosure as required, which is not specifically limited herein.

Some embodiments of the present disclosure further provide a method for preparing the display panel. The method for preparing the display panel shown in FIG. 1 is exemplified herein, which is described in detail below with reference to the accompanying drawings.

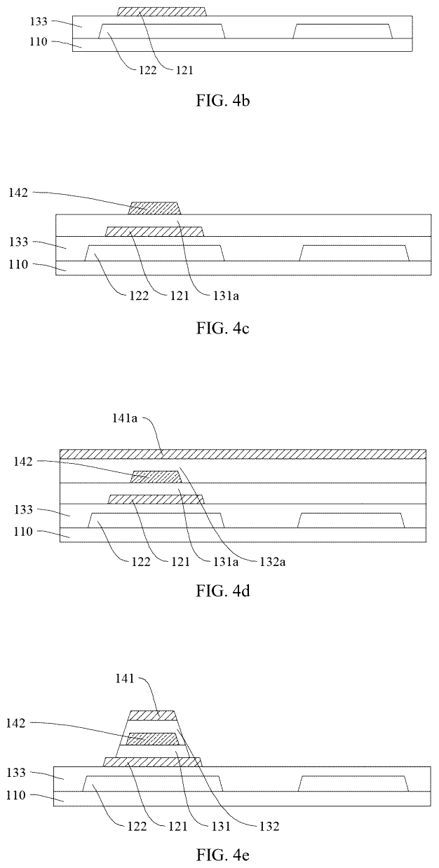

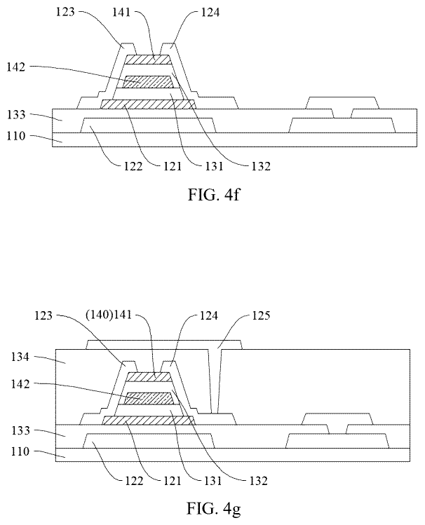

Referring to FIG. 4a, the substrate 110 on which the gate 122, the first gate wiring, and other wiring structures are formed is provided.

Referring to FIG. 4b, the third insulating layer 133 is disposed on the substrate 110 and the gate 122, and the active portion 121 is formed on the third insulating layer 133.

Referring to FIG. 4c, a first insulating film 131a is formed on the active portion 121, and the hydrogen blocking portion 142 is formed on the first insulating film 131a.

Referring to FIG. 4d, a second insulating film 132a is formed on the first insulating film 131a and the hydrogen blocking portion 142, and a metal oxide semiconductor film 141a is formed on the second insulating film 132a.

Referring to FIG. 4e, the first insulating thin film 131a, the second insulating thin film 132a, and the metal oxide semiconductor thin film 141a are patterned so that the hydrogen trapping portion 141 is formed by the metal oxide semiconductor thin film 141a, the second insulating layer is formed by the second insulating thin film 132a, and the first insulating layer 131 is formed by the first insulating thin film 131a.

Referring to FIG. 4f, the source 123 and the drain 124 are formed, in which the source 123 extends from the first end of the active portion 121 along sidewalls of the first insulating layer 131 and the second insulating layer 132 to the first end of the hydrogen trapping portion 141, and the drain 124 extends from the second end of the active portion 121 along another sidewalls of the first insulating layer 131 and the second insulating layer 132 to the second end of the hydrogen trapping portion.

Referring to FIG. 4g, the fourth insulating layer 134 is formed on the third insulating layer 133, the source 123, the drain 124, and the hydrogen trapping portion 141, and the electrode portion 125 is formed on the fourth insulating layer 134. The electrode portion 125 is connected to the drain 124 through the via hole in the fourth insulating layer 134. Finally, the preparation is completed.

Other embodiments of the present disclosure further provide a display device including the display panel described in the above embodiments. The display device includes but is not limited to a mobile phone, a smart watch, a tablet computer, a notebook computer, a television, and the like.

The display panel and the display device according to the embodiments of the present disclosure have been described in detail in the context. The principles and implementations of the present disclosure have been described with reference to specific embodiments. The description of the above embodiments is provided merely to help understand the present disclosure and the core idea thereof. Variations will occur and it is clear to those skilled in the art in both the detailed implementations and the scope of present disclosure in accordance with the teachings of the present disclosure. In view of the foregoing, the present description should not be construed as limiting the embodiments of the present disclosure.

What is claimed is:

1. A display panel comprising:
a substrate; and
a thin film transistor disposed on the substrate and comprising an active portion;
wherein the display panel further comprises a first insulating layer disposed on a side of the active portion away from the substrate, and a protective portion disposed on a side of the first insulating layer away from the substrate; an orthographic projection of the protective portion on the substrate at least partially covers an orthographic projection of the active portion on the substrate; and the protective portion comprises a hydrogen blocking portion and a hydrogen trapping portion that are stacked in a direction perpendicular to the substrate.

2. The display panel according to claim 1, wherein a material of the hydrogen trapping portion is selected from a metal oxide semiconductor material, and a material of the hydrogen blocking portion is selected from a metal material.

3. The display panel according to claim 2, wherein the thin film transistor further comprises a gate, a source, and a drain; wherein the gate is disposed on a side of the active portion close to the substrate, and the source and the drain are overlapped with opposite ends of the active portion, respectively.

4. The display panel according to claim 3, wherein an orthographic projection of the source, the drain, and the hydrogen blocking portion on the substrate cover an orthographic projection of the active portion on the substrate.

5. The display panel according to claim 3, wherein the display panel comprises a first gate wiring and a second gate wiring, wherein the first gate wiring is electrically connected to the gate, and the second gate wiring is electrically connected to the hydrogen blocking portion.

6. The display panel according to claim 5, wherein a second insulating layer is further provided between the hydrogen trapping portion and the hydrogen blocking portion, and the source and the drain are overlapped with opposite ends of the hydrogen trapping portion, respectively.

7. The display panel according to claim 6, wherein the hydrogen trapping portion is disposed on a side of the hydrogen blocking portion close to the active portion, the source is configured to extend from a first end of the active portion along a sidewall of the first insulating layer to a first end of the hydrogen trapping portion, and the drain is configured to extend from a second end of the active portion along another sidewall of the first insulating layer to a second end of the hydrogen trapping portion.

8. The display panel according to claim 6, wherein the hydrogen trapping portion is disposed on a side of the hydrogen blocking portion away from the active portion, the source is configured to extend from a first end of the active portion along sidewalls of the first insulating layer and the second insulating layer to a first end of the hydrogen trapping portion, and the drain is configured to extend from a second end of the active portion along another sidewalls of the first insulating layer and the second insulating layer to a second end of the hydrogen trapping portion.

9. The display panel according to claim 6, wherein a material of the active portion is same as a material of the hydrogen trapping portion.

10. A display device comprising a display panel, the display panel comprising:
a substrate; and
a thin film transistor disposed on the substrate and comprising an active portion;
wherein the display panel further comprises a first insulating layer disposed on a side of the active portion away from the substrate, and a protective portion disposed on a side of the first insulating layer away from the substrate; an orthographic projection of the protective portion on the substrate at least partially covers an orthographic projection of the active portion on the substrate, and the protective portion comprises a hydrogen blocking portion and a hydrogen trapping portion that are stacked in a direction perpendicular to the substrate.

11. The display device according to claim 10, wherein a material of the hydrogen trapping portion is selected from a metal oxide semiconductor material, and a material of the hydrogen blocking portion is selected from a metal material.

12. The display device according to claim 11, wherein the thin film transistor further comprises a gate, a source, and a drain; wherein the gate is disposed on a side of the active portion close to the substrate, and the source and the drain are overlapped with opposite ends of the active portion, respectively.

13. The display device according to claim 12, wherein an orthographic projection of the source, the drain, and the hydrogen blocking portion on the substrate cover an orthographic projection of the active portion on the substrate.

14. The display device according to claim 12, wherein the display panel comprises a first gate wiring and a second gate wiring, wherein the first gate wiring is electrically connected to the gate, and the second gate wiring is electrically connected to the hydrogen blocking portion.

15. The display device according to claim 14, wherein a second insulating layer is further provided between the hydrogen trapping portion and the hydrogen blocking portion, and the source and the drain are overlapped with opposite ends of the hydrogen trapping portion, respectively.

16. The display device according to claim 15, wherein the hydrogen trapping portion is disposed on a side of the hydrogen blocking portion close to the active portion, the source is configured to extend from a first end of the active portion along a sidewall of the first insulating layer to a first end of the hydrogen trapping portion, and the drain is configured to extend from a second end of the active portion along another sidewall of the first insulating layer to a second end of the hydrogen trapping portion.

17. The display device according to claim 15, wherein the hydrogen trapping portion is disposed on a side of the hydrogen blocking portion away from the active portion, the source is configured to extend from a first end of the active portion along sidewalls of the first insulating layer and the second insulating layer to a first end of the hydrogen trapping portion, and the drain is configured to extend from a second end of the active portion along another sidewalls of the first insulating layer and the second insulating layer to a second end of the hydrogen trapping portion.

18. The display device according to claim 15, wherein a material of the active portion is same as a material of the hydrogen capture portion.
